(19) United States
(12) Patent Application Publication
(10) Pub. No.: US 2026/0090415 A1
(43) Pub. Date: Mar. 26, 2026

(54) A Method of Forming a Power Module Connection

(71) Applicant: Infineon Technologies AG, Neubiberg (DE)

(72) Inventor: Georg Troska, Fröndenberg (DE)

(21) Appl. No.: 18/895,952

(22) Filed: Sep. 25, 2024

(51) Int. Cl. H01L 23/498; H01L 21/48

(52) U.S. Cl. CPC H10W 70/65; H10W 70/093; H10W 90/701

(57) ABSTRACT

A method of forming power module connections includes removing an electrically insulative coating from each of a first section and a second section of an elongated electrically conductive body, bending the elongated electrically conductive body in one or more dimensions to form a bent segment of the elongated electrically conductive body, severing the bent segment of the elongated electrically conductive body from a bulk of the elongated electrically conductive body such that each of the first section and the second section of the elongated electrically conductive body is at an end of the severed bent segment or is between ends of the severed bent segment, securing the bent segment to a frame of a power module, attaching the frame to a substrate of the power module, attaching at least one power semiconductor die to the substrate, and attaching the first section to the substrate or a power semiconductor die.

### BACKGROUND

Demand for electronic modules for power applications, commonly referred to as power modules, continues to increase rapidly across a wide range of industries, including automotive, consumer electronics, renewable energy, manufacturing, and medical, among many others. Developments in semiconductor materials such as silicon carbide (SiC) and gallium nitride (GaN) have enabled such power modules to be manufactured with advantageous features such as smaller footprint, higher voltage and current capabilities, and faster switching speeds.

A power module typically includes one or more power semiconductor dies attached to a substrate and enclosed in a housing, and one or more power module connections that provide an externally accessible electrical interface to the power semiconductor die(s). Specifically, each power module connection includes an internal end attached to the substrate (e.g., to a trace or a pad) or a power semiconductor die, and an external end providing an external connection interface (e.g., a pin, a threaded nut, a segment of wire), with the internal end and the external end joined by an elongated electrically conductive body or, in some instances, themselves being ends of the elongated electrically conductive body. Some applications of power modules require a specific layout of the external connection interfaces, and some substrates used in power modules have a fixed layout of the pads and/or traces that are electrically coupled to the power semiconductor die(s). Power modules having fixed positions for both the external connection interfaces and the substrate pads/traces thus require the power module connections to be designed and structured accordingly to accommodate these fixed layouts, often requiring changes in design and tooling to fabricate the connections, potentially increasing manufacturing cycle time and costs. Additionally, methods for electrically isolating the power module connections inside the housing of the power module, such as applying an electrically insulative gel, may also increase manufacturing cost and, in some instances, are associated with reliability concerns.

Thus, there is a need for a cost-effective and short cycle time solution for forming reliable power module connections that are customizable to a variety of external connection interface and internal pad/trace layouts.

### SUMMARY

According to an embodiment of method of forming power module connections, the method comprises: removing an electrically insulative coating from each of a first section and a second section of an elongated electrically conductive body; bending the elongated electrically conductive body in one or more dimensions to form a bent segment of the elongated electrically conductive body; severing the bent segment of the elongated electrically conductive body from a bulk of the elongated electrically conductive body such that each of the first section and the second section of the elongated electrically conductive body is at an end of the severed bent segment or is between ends of the severed bent segment; securing the bent segment to a frame of a power module; attaching the frame to a substrate of the power module; attaching at least one power semiconductor die to the substrate; and attaching the first section of the elongated electrically conductive body to the substrate or one of the power semiconductor dies.

According to an embodiment of a power module, the power module comprises: at least one power semiconductor die attached to a substrate; a frame attached to the substrate; and an elongated electrically conductive body segment secured to the frame and comprising: a first exposed section; a second exposed section; an unexposed section bent in one or more dimensions; and an electrically insulative material coating the unexposed section but not the first exposed section or the second exposed section, wherein the first exposed section of the elongated electrically conductive body segment is attached to the substrate.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIGS. 1A-1D illustrate views of a power module, according to an embodiment.

FIGS. 2A-2F illustrate forming a bent segment of a power module connection, according to an embodiment.

FIGS. 3A-3G illustrate forming a bent segment of a power module connection, according to an embodiment.

FIGS. 4A-4D illustrate forming a bent segment of a power module connection, according to an embodiment.

FIG. 5 illustrates forming a bent segment of a power module connection, according to an embodiment.

FIGS. 6A and 6B illustrate forming a bent segment of a power module connection, according to an embodiment.

FIGS. 7A-7E illustrate cross-sectional views of an elongated electrically conductive body, according to embodiments.

FIG. 8 illustrates attaching a power semiconductor die to a substrate of a power module, according to an embodiment.

FIGS. 9A-9E illustrate securing bent segments of power module connections to a frame of a power module, according to embodiments.

FIG. 10 illustrates attaching a frame and sections of bent segments of an elongated electrically conductive body secured to the frame to a substrate to produce a power module, according to an embodiment.

FIG. 11 illustrates adding an insulating gel to a volume of a power module, according to an embodiment.

### DETAILED DESCRIPTION

Described herein are a power module having power module connections each comprising a bent segment of a pre-insulated elongated electrically conductive body, and a method of making such power module connections. According to the embodiments described herein, each segment of pre-insulated elongated electrically conductive body of a power module connection includes one or more bends that enable the segment to span the distance between an internal connection point and an external connection point of the power module. Hereafter, these segments will be referred to as bent segments. The term “bent profile” is used herein to describe the shape, placement, angles, quantity, and other attributes of the bend(s) of a particular bent segment. One more power module connections of a particular power module may include one or more bent segments having a bent profile that is different than the bent profile of one or more other bent segments in order to accommodate the layout of the internal connections and the external connections of the particular power module.

According to the embodiments described herein, bent segments having different bent profiles may be formed sequentially using a single manufacturing tool. Such an approach may provide the ability to rapidly change the design of the bent segments with a simple program change, which may enable faster manufacturing of power module connections to accommodate power modules with different external connection and internal connection layouts. This may reduce tooling and manufacturing costs and manufacturing cycle time, for example by reducing or eliminating the time required to design, produce, and/or change the tooling. The ability to sequentially produce bent segments having different designs may also streamline manufacturing by enabling all of the power module connections for a given power module to be produced within a shorter period of time (e.g., compared to batch processing power module connections of a single design), potentially providing further cost and cycle time benefits. Additionally, forming the bent segments using a programmable manufacturing tool may enable power module connection designs having higher complexity and/or improved precision in placement of the bends compared to other methods of producing power module connections, and may enable greater flexibility in the shape (e.g., the cross-section) of the elongated electrically conductive body used to form the bent segments.

Described next, with reference to the figures, are exemplary embodiments of a power module and a method of forming power module connections.

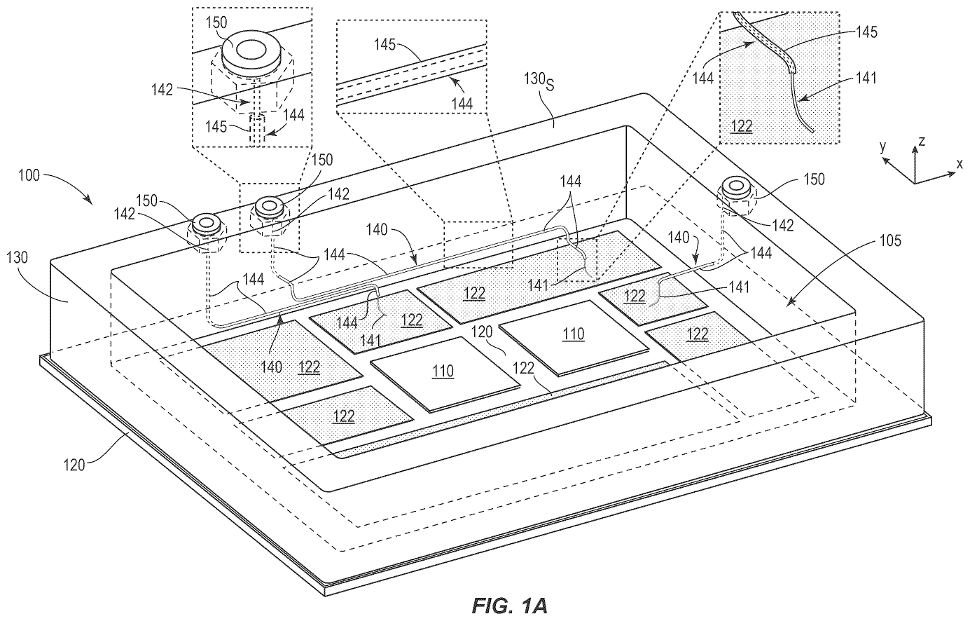

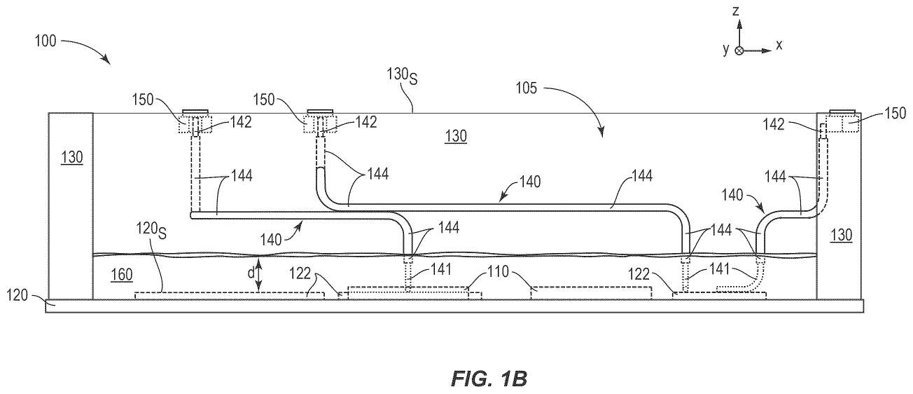

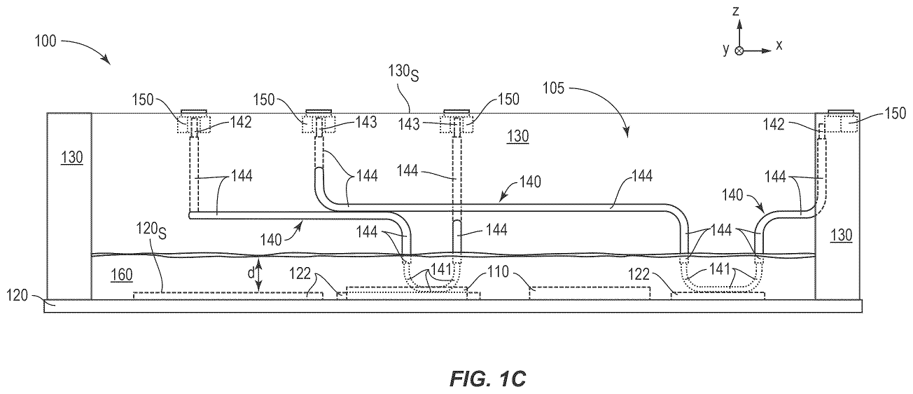

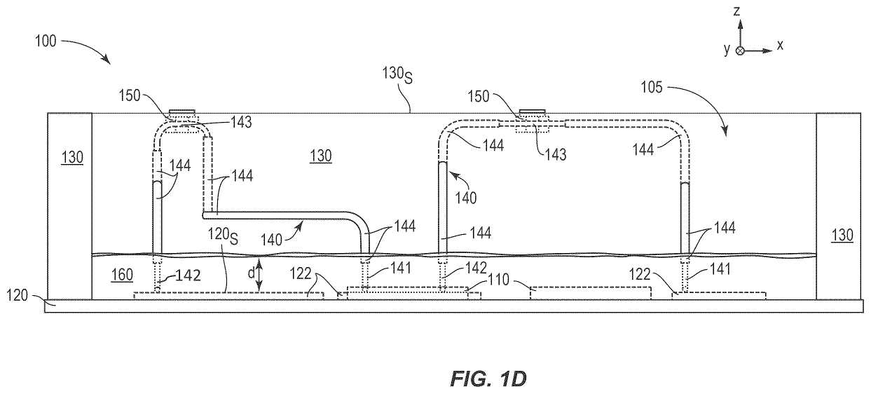

FIGS. 1A-1D illustrate views of a power module 100, according to an embodiment. Specifically, FIG. 1A illustrates a perspective view of the power module 100 and FIGS. 1B-1D illustrate cross-sectional side views of the power module 100.

The power module 100 includes at least one power semiconductor die 110 attached to a substrate 120. For illustrative purposes, two power semiconductor dies 110 are shown in the power module 100 of FIGS. 1A-1D, although any of the examples of the power module 100 described herein, including those illustrated in FIGS. 1A-1D, may include only one power semiconductor 110 or two or more power semiconductor dies 110. The power semiconductor dies 110 are enclosed in a volume 105 that is delimited by the substrate 120 and a frame 130. The frame 130 may be attached to the substrate 120, in this example along an outer perimeter of the substrate, using a glue, tape, or other adhesive, welding, etc. Alternatively, the substrate may be mounted to a baseplate (not shown) via solder, adhesive, sintering, etc., and the frame 130 mounted to the baseplate via threaded fasteners, adhesives, or other appropriate fastening methods. The power module 100 may include a top, lid, cover, or other structure that delimits an opposite side of the volume 105 from the substrate 120. This top, lid, cover, or other structure may be integrated with the frame 130 or may be provided as a separate piece but is omitted in FIGS. 1A-1D to better illustrate the features enclosed in the volume 105.

Each power semiconductor die 110 may include one or more devices, e.g., one or more transistors, diodes, resistors, capacitors, and/or other types of active or passive devices. One or more of the power semiconductor dies 110 included in the power module 100 may be a vertical power semiconductor die (e.g., a vertical power transistor die). For a vertical power transistor die, the primary current flow path is between the front and back sides of the power semiconductor die 110 (along the z direction in FIGS. 1A-1D). In one embodiment, one or more power semiconductor dies 110 are SiC transistor dies such as SiC power MOSFET (metal-oxide-semiconductor field-effect transistor) dies. One or more of the power semiconductor dies 110 included in the power module 100 may be a Si power MOSFET die, HEMT (high-electron mobility transistor) die, IGBT (insulated-gate bipolar transistor) die, JFET (junction filed-effect transistor) die, etc. If more than one power semiconductor die 110 is included in the power module 100, the power semiconductor dies 110 may all be of a similar or identical design (e.g., device type, structure, materials, dimensions, etc.), or some or each of the power semiconductor dies 110 may have different designs. Various arrangements of designs of power semiconductor dies 110 of the power module 100 are contemplated. Each power semiconductor die 110 included in the power module 100 and/or its constituent devices may be arranged to form all or part of a circuit of the power module 100, such as a DC/AC inverter, a DC/DC converter, an AC/DC converter, a DC/AC converter, an AC/AC converter, a multi-phase inverter, an H-bridge, motor driver, etc. In some examples, the power module 100 includes more than one power semiconductor die 110 and the circuit that includes the power semiconductor dies 110 is a half-bridge or full-bridge circuit.

Examples of the substrate 120 include a DCB (direct copper bonded) or AMB (active metal brazed) substrate, printed circuit board (PCB), lead frame, or other substrate, e.g., insulated metal substrate (IMS), etc. The substrate 120 illustrated herein includes a metallization layer 122 that includes metallic (e.g., copper, aluminum, an alloy) pads, traces, and/or islands that may each be electrically coupled to one or more of the power semiconductor dies 110 (e.g., directly coupled, electrically coupled by a bond wire, metallic ribbon, or other electrically conductive body).

The frame 130 may include one or more pieces of metal, plastic, composite, and/or another suitable material. In some examples, the frame 130 is an electrically insulative frame such as an electrically insulative molded frame. In one embodiment, the frame 130 is an electrically insulative molded frame formed from a mold compound. A mold compound is a plastic encapsulant typically formed from an organic resin such as an epoxy resin. The plastic encapsulant may include fillers such as non-melting inorganic materials. Catalysts may be used to accelerate the cure reaction of the organic resin. Other materials such as flame retardants, adhesion promoters, ion traps, stress relievers, colorants, etc. may be added to the plastic encapsulant, as appropriate. The mold compound may be formed by injection molding, compression molding, film-assisted molding (FAM), reaction injection molding (RIM), resin transfer molding (RTM), blow molding, etc.

According to an embodiment, the power module 100 includes a plurality of power module connections that each includes an elongated electrically conductive body segment 140 (e.g., a segment of wire or ribbon, an elongated bar, or another elongated body) secured to the frame 130. Each elongated electrically conductive body segment 140 includes a first exposed section 141, a second exposed section 142, and an unexposed section 144, and is bent in one or more dimensions. An electrically insulative material 145, for example polyether ether ketone (PEEK), polyimide (PI), polyphenylene sulfide (PPS), etc., coats the unexposed section 144 but not the first exposed section 141 or the second exposed section 142.

The first exposed section 141 of each elongated electrically conductive body segment 140 is attached to the substrate 120 or one of the power semiconductor dies 110 and thus electrically couples each elongated electrically conductive body segment 140 to one or more power semiconductor dies 110. In the example of the power module 100 of FIG. 1A, the first exposed sections 141 of the elongated electrically conductive body segments 140 are each attached to the metallization layer 122 of the substrate 120, although examples in which one or more of the first exposed section 141 are attached to other features of the substrate 120 or even directly to one or more power semiconductor dies 110 are contemplated. The metallization layer 122 of the substrate 120 may be patterned into island-like structures, e.g., as shown in FIG. 1A, to support different electric potentials (e.g., source, drain, and gate potentials).

Each elongated electrically conductive body segment 140 is secured to the frame 130 such that the second exposed section 142 or, optionally, a connection interface 150 attached to the second exposed section 142, is at least partly exposed from a surface 130_{S} of the frame 130. In such an arrangement, each second exposed section 142 or connection interface 150 provides an externally accessible interface for attaching the power module 100 to an external component or assembly (e.g., a busbar or a printed circuit board) and electrically coupling the one or more power semiconductor dies 110 of the power module 100 to the external component or assembly through the elongated electrically conductive body segments 140.

As noted, the connection interfaces 150 illustrated herein are optional and not a requirement of the power module connections. That is, in some examples, the second exposed section 142 of one or more elongated electrically conductive body segments 140 of the power module 100 may be at least partly exposed from the surface 130_{S} and an external component or assembly may be directly attached to the second exposed section 142 of such an elongated electrically conductive body segment 140 (e.g., by soldering or a press fit connection). In the example of the power module 100 described herein, each connection interface 150 is a nut, e.g., for a screw-type terminal of the power module 100. Other examples of a connection interface 150 include a rivet, a screw, a tab, or a pin, among others. The connection interfaces 150 of the power module 100 may all be of a single type or may be of different types.

FIGS. 1B-1D illustrate cross-sectional side views of some example configurations of the elongated electrically conductive body segments 140 and their arrangement in the power module 100. It should be clear, however, that the examples presented herein are not limiting and other configurations and/or arrangements are contemplated (e.g., various combinations of the elongated electrically conductive body segments 140 illustrated in FIGS. 1B-1D).

In each of the examples of FIGS. 1B-1D, the first exposed section 141 of each elongated electrically conductive body segment 140 is attached to the substrate 120, specifically to the metallization layer 122 of the substrate 120. As noted with reference to FIG. 1A, examples in which one or more of the first exposed sections 141 are attached to other features of the substrate 120 or directly to one or more power semiconductor dies 110 are contemplated.

In the example of FIG. 1B, the first exposed section 141 and the second exposed section 142 are each at an end of the electrically conductive body segment 140, with the unexposed section 144 extending between the first exposed section 141 and the second exposed section 142. A connection interface 150, in this example a nut, is attached to each second exposed section 142 and is at least partly exposed from the surface 130_{S} of the frame 130, although as noted previously, other types of connection interfaces 150 may be used. Additionally, instead of a connection interface 150, the second exposed section 142 of one or more elongated electrically conductive body segments 140 of the power module 100 illustrated in FIG. 1B may be at least partly exposed from the surface 130_{S}.

In the example of FIG. 1C, the first exposed sections 141 are intermediate sections positioned between ends of the electrically conductive body segments 140. Each electrically conductive body segment 140 of FIG. 1C includes a third exposed section 143 at an end of the electrically conductive body segment 140, with each first exposed section 141 positioned between the second exposed section 142 and the third exposed section 143 of the respective electrically conductive body segment 140. A connection interface 150, in this example a nut, is attached to each third exposed section 143 and is at least partly exposed from the surface 130_{S} of the frame 130, although as noted previously, other types of connection interfaces 150 may be used. Additionally, instead of a connection interface 150, the third exposed section 143 of one or more elongated electrically conductive body segments 140 of the power module 100 illustrated in FIG. 1C may be at least partly exposed from the surface 130_{S}.

In the example of FIG. 1D, the first exposed sections 141 and the second exposed sections 142 are each at an end of a respective electrically conductive body segment 140. Each electrically conductive body segment 140 includes a third exposed section 143 that is an intermediate section positioned between the first exposed section 141 and the second exposed section 142. A connection interface 150, in this example a nut, is attached to each third exposed section 143 and is at least partly exposed from the surface 130_{S} of the frame 130, although as noted previously, other types of connection interfaces 150 may be used. Additionally, instead of a connection interface 150, the third exposed section 143 of one or more elongated electrically conductive body segments 140 of the power module 100 illustrated in FIG. 1D may be at least partly exposed from the surface 130_{S}. In the example of FIG. 1D, both the first exposed section 141 and the second exposed section 142 of each elongated electrically conductive body segment 140 are attached to the substrate 120, specifically to the metallization layer 122 of the substrate 120. Examples in which one or more of the first exposed sections 141 and/or second exposed sections 142 are attached to other features of the substrate 120 or directly to one or more power semiconductor dies 110 are contemplated.

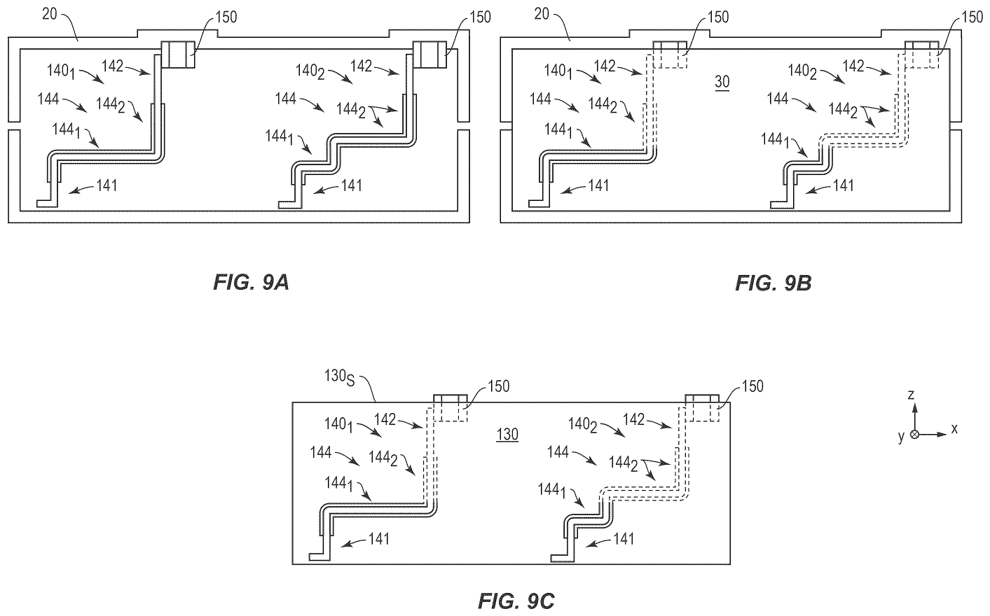

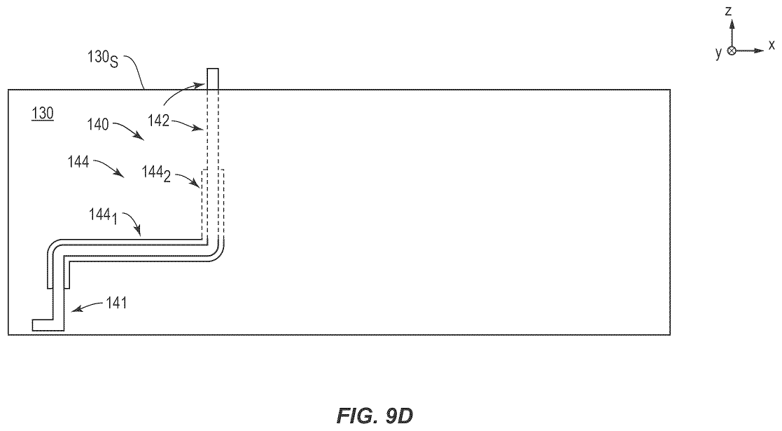

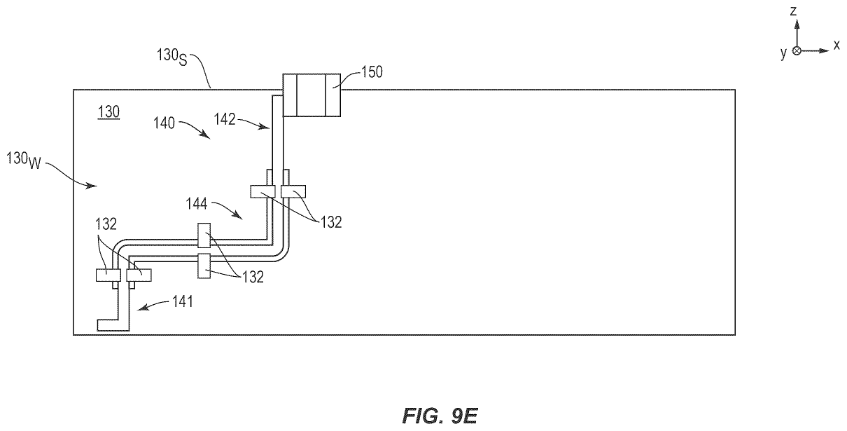

In the example of the power module 100 of FIGS. 1A-1D, a portion of each elongated electrically conductive body segment 140 and a portion of each connection interface 150 are embedded in the frame 130. As will be described in more detail with reference to FIGS. 9A-9D, securing the elongated electrically conductive body segments 140 to the frame 130 in this manner may be accomplished by forming the frame 130 from a mold compound, that is, forming a molded frame 130, and inserting the portions of the elongated electrically conductive body segments 140 and the connection interfaces 150 into the mold while forming the molded frame 130. Other means of securing the elongated electrically conductive body segments 140 to the frame 130 are contemplated. Some of these will be described with reference to FIG. 9E.

As illustrated in FIGS. 1B-1D, the power module 100 may include an insulating gel 160 at least partly filling the volume 105. The insulating gel 160 is disposed in the volume 105 such that the substrate 120 and the first exposed section 141 of each elongated electrically conductive body segment 140 are at least partly covered by the gel 160. In the example of FIG. 1D, the second exposed section 142 of each elongated electrically conductive body segment 140 is also at least partly covered by the gel 160. Since the unexposed section 144 of each elongated electrically conductive body segment 140 is coated by an electrically insulative material 145, at least the upper part of the unexposed section 144 and the second exposed section 142 may both be uncovered by the gel 160. The insulating gel 160 is made of a different material than the electrically insulative material 145 coating the elongated electrically conductive body segments 140. For example, the insulating gel 160 may be a potting compound.

An insulating gel such as the insulating gel 160 of the power module 100 is included to electrically insulate those features of a power module having exposed electrical conductors, such as substrates having traces and/or contact pads, the semiconductor dies themselves, and any uninsulated power module connections. An example power module that uses uninsulated power module connections, for example those stamped or punched from metallic sheets, but is otherwise similar to the power module 100 of FIGS. 1A-1D may require an amount of insulating gel that is sufficient to cover large portions of the uninsulated power module connections. In contrast, forming the power module connections of the power module 100 from the elongated electrically conductive body segments 140 which are partly coated with the electrically insulative material 145 and embedding portions of the elongated electrically conductive body segments 140 in the frame 130 as illustrated in FIGS. 1A-1D may enable less insulating gel 160 to be used. Specifically, the frame 130 of the power module 100 provides the electrical isolation for the exposed second sections 142 and the electrically insulative material 145 provides the electrical isolation for the unexposed sections 144 of the elongated electrically conductive body segments 140.

Thus, for the power module 100 of FIGS. 1A-1D, the insulating gel 160 is only required to cover and electrically isolate the first exposed sections 141 of the elongated electrically conductive body segments 140, in addition to the power semiconductor dies 110 and the metallization layer 122 of the substrate 120. In some examples, filling the volume 105 with the insulating gel 160 to a depth d of less than 10 millimeters is sufficient to cover and electrically isolate the first exposed sections 141, where the depth d is measured from a surface 120_{S} of the substrate 120 to which the first exposed sections 141 are attached, in this example, a surface 120_{S} of the metallization layer 122. In some examples of the power module 100, filling the volume 105 with the insulating gel 160 to a depth d of less than 5 millimeters is sufficient to cover and electrically isolate the first exposed sections 141 of the elongated electrically conductive body segments 140. Thus, the power module 100 illustrated in FIGS. 1A-1D may provide a material cost savings by requiring less insulating gel 160 to provide sufficient insulation of the power module connections. Additionally, using less insulating gel 160 may reduce the risk of failures associated with cracking and/or overfilling of the insulating gel 160, potentially providing a reliability benefit in addition to the potential material cost savings.

The remainder of this disclosure describes and illustrates an exemplary method of forming power module connections of the power module 100 of FIGS. 1A-1D. It should be noted that x, y, and z axes are included in subsequent figures for reference but do not necessarily correspond to the x, y, and z axes of FIGS. 1A-1D.

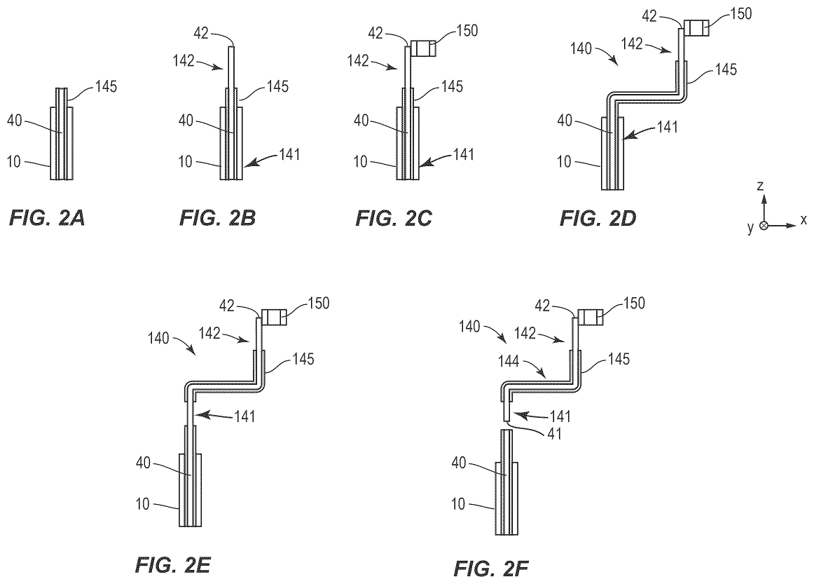

FIGS. 2A-2F illustrate a method of forming a bent segment 140 of a power module connection, according to an embodiment. The method of forming the bent segment 140 in FIGS. 2A-2F is one example of forming an elongated electrically conductive body segment 140 of FIGS. 1A-1D (e.g., bending an elongated electrically conductive body segment 140 in one or more dimensions), and the term “bent segment” is used in place of “elongated electrically conductive body segment” hereafter to simplify the subsequent description. Thus, it should be understood that any bent segment 140 described herein may be an example of an elongated electrically conductive body segment 140 of the power module 100 of FIGS. 1A-1D. Furthermore, any features of a bent segment 140 may correspond to similarly numbered features of an elongated electrically conductive body segment 140 of FIGS. 1A-1D. Additionally, the steps of FIGS. 2A-2F may be completed in a different order than what is illustrated. Some such examples will be described.

FIG. 2A illustrates providing an elongated electrically conductive body 40 having an electrically insulative coating 145. The elongated electrically conductive body 40 may be any electrically conductive wire, ribbon, elongated bar, or other elongated body. The elongated electrically conductive body 40 may be formed from a metal such as copper, aluminum, an alloy, etc., and may be provided on a spool or in another bulk form. In the example of FIG. 2A, an end of the elongated electrically conductive body 40 is threaded through and extends from an opening of a machine 10. The machine 10 may be anything from a manual or automated wire feeder to a manufacturing tool that is configured to complete all of the steps illustrated in FIGS. 2A through 2F, as will be described later in more detail. The elongated electrically conductive body 40 as illustrated in FIG. 2A may be referred to as the bulk of the elongated electrically conductive body 40 in subsequent steps.

FIG. 2B identifies a first section 141 and a second section 142 of the elongated electrically conductive body 40 that will be referenced in this and subsequent steps. In this example. the second section 142 is positioned at the end of the elongated electrically conductive body 40 extending from the opening of the machine 10, and the first section 141 is positioned inward along the elongated electrically conductive body 40 from the second section 142.

FIG. 2B illustrates the elongated electrically conductive body 40 after the tool 10 removes the electrically insulative coating 145 from the second section 142 of the elongated electrically conductive body 40, e.g., using a wire stripping technique. At this juncture, the second section 142 is at what will be the second end 42 of the bent segment 140 upon completion of the method illustrated in FIGS. 2A through 2F.

FIG. 2C illustrates attaching a connection interface 150 to the second section 142 of the elongated electrically conductive body 40. As noted previously, the connection interface 150 is optional and thus the step illustrated in FIG. 2C is likewise optional. Additionally, while the attaching of the connection interface 150 to the second section 142 of the elongated electrically conductive body 40 is shown during the step of FIG. 2C, the connection interface 150 may be attached to the second section 142 at any step after removing the electrically insulative coating 145 from the second section 142 of the elongated electrically conductive body 40.

Attaching the connection interface 150 to the second section 142 of the elongated electrically conductive body 40 as illustrated in FIG. 2C may include soldering, diffusion soldering, sintering, gluing, welding, crimping, etc. of the connection interface 150 to the second end 142. The connection interface 150 illustrated in FIGS. 2C-2F is a nut, although, as noted previously with reference to FIGS. 1A and 1B, the connection interface 150 may be a rivet, a screw, a tab, a pin, or another type.

FIG. 2D illustrates bending the elongated electrically conductive body 40 in one or more dimensions (x, y, and/or z) to form the bent segment 140. The bending may include twisting of the elongated electrically conductive body 40 in any of x, y, and/or z dimensions.

FIG. 2E illustrates the elongated electrically conductive body 40 after the tool 10 removes the electrically insulative coating 145 from the first section 141 of the elongated electrically conductive body 40, e.g., using a wire stripping technique. At this juncture, the first section 141 is at what will be the first end 41 of the bent segment 140 upon completion of the method illustrated in FIGS. 2A through 2F. In some examples, the electrically insulative coating 145 may be removed from the first section 141 before or simultaneously with removing the electrically insulative coating 145 from the second section 142 of the elongated electrically conductive body 40.

FIG. 2F illustrates severing the bent segment 140 from the bulk of the elongated electrically conductive body 40. At this juncture, the bent segment 140 becomes an example of an elongated electrically conductive body segment 140 of FIGS. 1A-1D, having the first section 141 from which the electrically insulative coating 145 was removed (corresponding to a first exposed section 141 or a second exposed section 142 of FIGS. 1A-1D), the second section 142 from which the electrically insulative coating 145 was removed (corresponding to a first exposed section 141 or a second exposed section 142 of FIGS. 1A-1D), an unexposed section 144, and the electrically insulative material 145 coating the unexposed section 144 (i.e., the electrically insulative coating 145 of FIGS. 1A-1D).

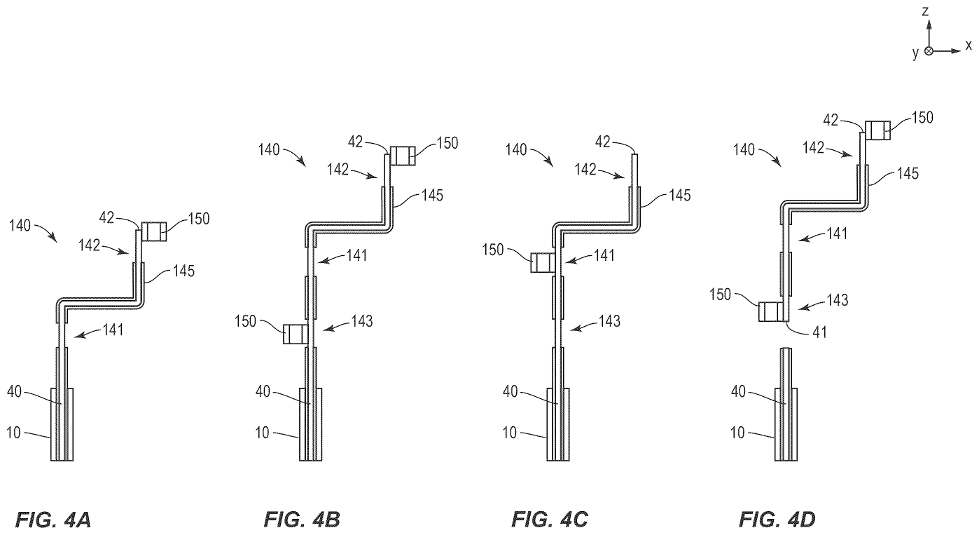

Unless otherwise noted, the first sections 141 and the second sections 142 of the bent segments 140 will be described and illustrated hereafter to correspond to the first exposed sections 141 and the second exposed sections 142, respectively, of the elongated electrically conductive body segments 140 of FIGS. 1A-1D, for example when describing attaching the bent segment 140 to the substrate 120. However, it should be noted that the first section 141 and the second section 142 of a bent segment 140 illustrated herein may each correspond to any of the exposed sections 141, 142, or 143 of an elongated electrically conductive body segment 140 of the power module 110 of FIGS. 1A-1D. One such example will be described with reference to FIGS. 4A-4D.

As noted previously, in some examples the steps of FIGS. 2A-2F may be completed in a different order than what is illustrated. Additionally, forming the bent segment 140 may include variations of the steps illustrated and/or may include completing additional steps. For example, a connection interface 150 may be attached to the first section 141 of the bent segment 140 instead of or in addition to attaching a connection interface 150 to the second section 142 of the bent segment 140. Forming the bent segment 140 may include processing one or both of the first section 141 and/or the second section 142 of the bent segment 140. Examples include processing the first section 141 and/or the second section 142 for a soldering (e.g., a hot air solder leveling (HASL or HAL) process, plating the first section 141 and/or the second section 142, pre-attaching solder to the first section 141 and/or the second section 142, and adding a second wire layer or other metallic body to enlarge the contact. Other examples will be described with reference to subsequent figures.

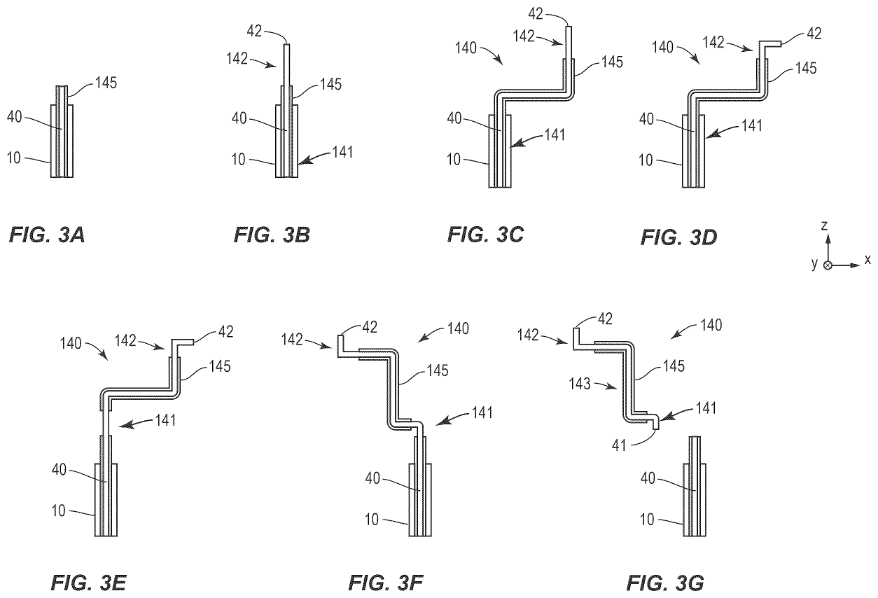

FIGS. 3A-3G illustrate forming a bent segment 140 of a power module connection, according to an embodiment. Specifically, the steps illustrated in FIGS. 3A-3G illustrate one alternative example to steps of forming the bent segment 140 illustrated in FIGS. 2A-2F. As with the steps of FIGS. 2A-2F, the steps of FIGS. 3A-3G may be completed in a different order than what is illustrated. Unless otherwise noted, details of completing the steps of FIGS. 3A-3G are similar to the corresponding steps of FIGS. 2A-2F.

FIG. 3A (corresponding to FIG. 2A) illustrates providing an elongated electrically conductive body 40 having an electrically insulative coating 145. FIG. 3B (corresponding to FIG. 2B) illustrates removing the electrically insulative coating 145 from the second section 142 of the elongated electrically conductive body 40. FIG. 3C (corresponding to FIG. 2D) illustrates bending the elongated electrically conductive body 40 in one or more dimensions to form the bent segment 140. FIG. 3D illustrates bending the second section 142 of the elongated electrically conductive body 40 in one or more dimensions (x, y, and/or z). FIG. 3E (corresponding to FIG. 2E) illustrates removing the electrically insulative coating 145 from the first section 141 of the elongated electrically conductive body 40. FIG. 3F illustrates bending the first section 141 in one or more dimensions, which can include twisting of the elongated electrically conductive body 40. FIG. 3G (corresponding to FIG. 2F) illustrates severing the bent segment 140 from the bulk of the elongated electrically conductive body 40.

Bending the second section 142 and the first section 141 of the elongated electrically conductive body 40 as illustrated in FIGS. 3D and 3F, respectively, may be done to form the respective first and second sections 141 and 142 for contact during later processing (e.g., with the substrate 120, with an external component or assembly). For example, one or both of the first end 141 and the second end 142 may be bent into a spiral to form a threading, a U-shape, V-shape, or radial spiral for flat contact geometries, a spring-loaded contact, etc.

FIGS. 4A-4D illustrate forming a bent segment of a power module connection, according to an embodiment. Specifically, the steps illustrated in FIGS. 4A-4D illustrate an alternative example to steps of forming the bent segment 140 illustrated in FIGS. 2A-2F and FIGS. 3A-3G, in which the electrically insulative coating 145 is removed from a third section 143 of the elongated electrically conductive body 40.

FIG. 4A, corresponding to FIGS. 2E and 3E, illustrates the elongated electrically conductive body 40 after the tool 10 removes the electrically insulative coating 145 from both the second section 142 and the first section 141 of the elongated electrically conductive body 40.

FIGS. 4B-4C illustrate the elongated electrically conductive body 40 after the tool 10 removes the electrically insulative coating 145 from the third section 143 of the elongated electrically conductive body 40, e.g., using a wire stripping technique. At this juncture, the third section 143 is at what will be the first end 41 of the bent segment 140 upon completion of the method illustrated in FIGS. 4A-4D, and the first section 141 becomes an intermediate section of the bent segment 140 between the second section 142 and the third section 143. The electrically insulative coating 145 may be removed from the third section 143 before, after, or simultaneously with removing the electrically insulative coating 145 from the first section 141 and the second section 142 of the elongated electrically conductive body 40. In the example of FIG. 4B, a connection interface 150 is attached to the third section 143. This example step may correspond to forming an elongated electrically conductive body 40 of FIG. 1C. FIG. 4C illustrates an example in which a connection interface 150 is not attached to the second section 142 and instead is attached to the first section 141. This example step may correspond to forming an elongated electrically conductive body 40 of FIG. 1D, with the first section 141 of FIG. 4C corresponding to the third exposed section 143 of FIG. 1D. Other steps may be completed on the third section 143, e.g., processing the third section 143 soldering and/or bending the third section 143 in one or more dimensions for contact, as described previously.

FIG. 4D illustrates severing the bent segment 140 from the bulk of the elongated electrically conductive body 40. At this juncture, the bent segment 140 becomes an example of an elongated electrically conductive body segment 140 of FIGS. 1C and 1D, having the first section 141 from which the electrically insulative coating 145 was removed (corresponding to a first exposed section 141 of FIG. 1C or a third exposed section 143 of FIG. 1D), the second section 142 from which the electrically insulative coating 145 was removed (corresponding to a second exposed section 142 or a third exposed section 143 of FIG. 1C, or a second exposed section 142 or first exposed section 141 of FIG. 1D), the third exposed section from which the electrically insulative coating was removed (corresponding to a third exposed section 143 or a second exposed section 142 of FIG. 1C, or a first exposed section 141 or second exposed section 142 of FIG. 1D), an unexposed section 144, and the electrically insulative coating 145 coating the unexposed section 144 (i.e., the electrically insulative coating 145 of FIGS. 1C and 1D).

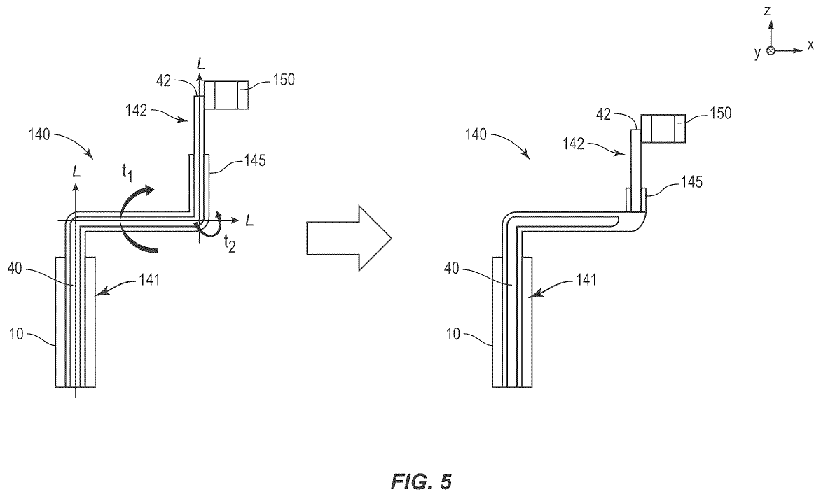

FIG. 5 illustrates forming a bent segment 140 of a power module connection, according to an embodiment. Specifically, FIG. 5 illustrates one example of bending the elongated electrically conductive body 40 in one or more dimensions to form a bent segment 140, e.g. during the steps illustrated in FIGS. 2D and 3C. In this example, bending the elongated electrically conductive body 40 in one or more dimensions comprises twisting the elongated electrically conductive body 40 about a longitudinal axis L of the elongated electrically conductive body 40. In this example a first twist t₁ and a second twist t₂ in an opposite direction are made about a segment of the longitudinal axis L that is parallel to the x direction, resulting in a segment of the elongated electrically conductive body 40 that originally extended parallel to the z direction being bent to extend parallel to the y direction. This is only one example, and other variations and combinations of bend positions, angles, directions, etc. are contemplated.

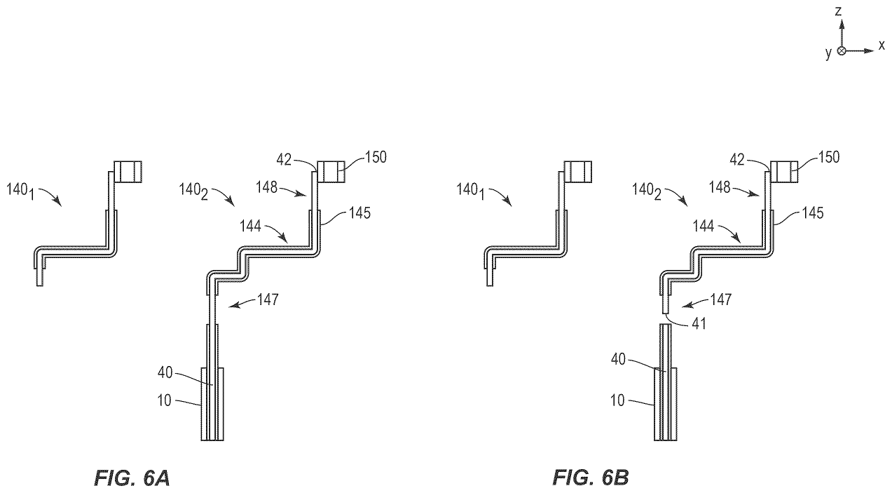

FIGS. 6A and 6B illustrate forming a bent segment of a power module connection, according to an embodiment. Specifically, FIGS. 6A and 6B identify a first bent segment 140₁ having a first bent profile, which may be the bent segment 140 formed in FIGS. 2A-2F or FIGS. 3A-3G, and illustrates forming a second bent segment 140₂ having a second bent profile that is different than the first bent profile of the first bent segment 140₁. The second bent segment 140₂ may be formed from the same elongated electrically conductive body 40 using the same method used to form the first bent segment 140₁ and may be formed sequentially with the first bent segment 140₁. FIG. 6A illustrates removing the electrically insulative coating 145 from a third section 147 and a fourth section 148 of the elongated electrically conductive body 40 and bending the elongated electrically conductive body 40 in one or more dimensions to form the second bent segment 140₂. At this juncture, the fourth section 148 is at what will be the second end 42 of the second bent segment 140₂, respectively, upon completion of the method illustrated herein.

Like the first bent segment 140₁, a connection interface 150 may be attached to one or both of the fourth section 148 or the third section 147 of the second bent segment 140₂ using the same method used to attach a connection interface 150 to one or both of the second section 142 or the first section 141 of the first bent segment 140₁.

FIG. 6B illustrates severing the second bent segment 140₂ from the bulk of the elongated electrically conductive body 40 such that the third section 147 is at a first end 41 of the second bent segment 140₂ and the fourth section 148 is at the second end 42 of the second bent segment 140₂.

Forming the second bent segment 140₂ in FIGS. 6A and 6B may include any of the variations described previously with reference to FIGS. 2A-5. For example, the third section 147 and/or the fourth section 148 may be an intermediate section positioned between the first end 41 and the second end 42 of the second bent segment 140₂. Furthermore, the second bent segment 140₂ may include one or more additional sections from which the electrically insulative coating 145 was removed, e.g., as illustrated in FIGS. 4A-4D.

As noted above, the machine 10 of FIGS. 2A-6B may be a single manufacturing tool that is configured to complete all of the steps illustrated in FIGS. 2A-6B. That is, removing the electrically insulative coating 145 from sections of the elongated electrically conductive body 40 (the first section 141, the second section 142, the third section 143 of FIGS. 4A-4D, the third section 147 and the fourth section 148 of FIGS. 6A-6B, etc.), bending the elongated electrically conductive body 40 in one or more dimensions to form a bent segment 140, and severing the bent segment 140 from the bulk of the elongated electrically conductive body 40 may be completed using the machine 10. Utilizing such a manufacturing tool to form the bent segments 140 may provide numerous manufacturing cost and cycle time advantages. As an example, the machine 10 may perform the step of bending the elongated electrically conductive body 40 based on a program and may thus be capable of producing bent segments 140 having different shapes, sizes, bend positions and orientations, removing the electrically insulative coating 145 at different positions, removing different amounts of electrically insulative coating 145 from different sections, etc. sequentially without requiring changes to tooling (e.g., stamps or punches). Such a process may be used to sequentially produce the first bent segment 140₁ and the second bent segment 140₂ of FIGS. 6A and 6B, for example.

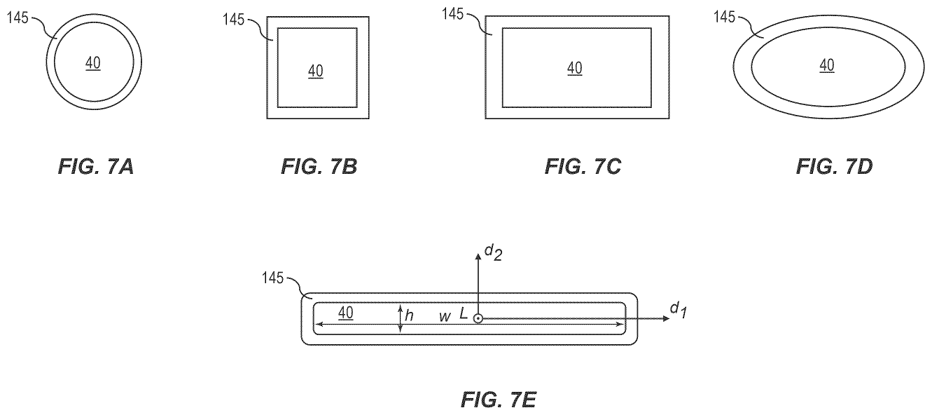

FIGS. 7A-7E illustrate cross-sectional views of the elongated electrically conductive body 40, according to embodiments. Specifically, each of FIGS. 7A-7E illustrates an example cross-section of the elongated electrically conductive body 40 used to form the bent segments 140 using the method described herein.

FIG. 7A illustrates the elongated electrically conductive body 40 having a round cross-section, e.g., like a round wire. FIG. 7B illustrates the elongated electrically conductive body 40 having a square cross-section, e.g., like a square wire. FIG. 7C illustrates the elongated electrically conductive body 40 having a rectangular cross-section, e.g., like a rectangular wire. FIG. 7D illustrates the elongated electrically conductive body 40 having an elliptical cross-section, e.g., like an elliptical wire.

FIG. 7E illustrates the elongated electrically conductive body 40 having a flattened profile, e.g., like a bar. The elongated electrically conductive body of this example has a width w in a first direction d₁ perpendicular to a longitudinal axis L of the elongated electrically conductive body 40 and a height h in a second direction d₂ perpendicular to the first direction d₁ and the longitudinal axis L of the elongated electrically conductive body 40, wherein the width w is greater than the height h.

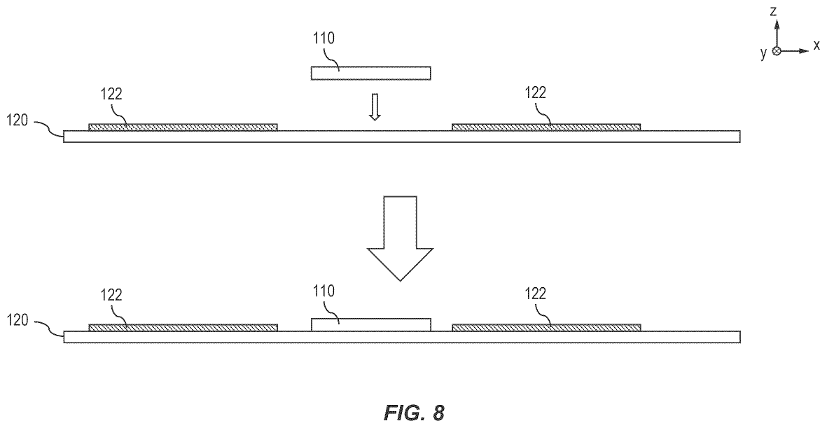

FIG. 8 illustrates attaching a power semiconductor die 110 to the substrate 120 of the power module 100, according to an embodiment. As noted above, the power module 100 may include two or more power semiconductor dies 110 which may also be attached to the substrate 120 using the step illustrated in FIG. 8. Attaching the power semiconductor die 110 to the substrate 120 may include soldering, diffusion soldering, welding, gluing, etc., to a metallization layer of the substrate 120.

FIGS. 9A-9E illustrate securing bent segments 140 of power module connections to the frame 130 of the power module 100, according to embodiments.

FIGS. 9A-9C illustrate securing the first bent segment 140₁ and the second bent segment 140₂ to the molded frame 130 that was introduced in the description of FIGS. 1A-1D. Specifically, FIGS. 9A-9C illustrate securing the first bent segment 140₁ and the second bent segment 140₂ to the molded frame 130 during formation of the molded frame 130.

FIG. 9A illustrates inserting a portion of the first bent segment 140₁ and a portion of the second bent segment 140₂ into a mold 20 shaped to form the molded frame 130.

FIG. 9B illustrates injecting a liquified mold compound 30 into the mold 20 such that the portion of the first bent segment 140₁ and the portion of the second bent segment 140₂ are embedded in the liquified mold compound 20. In this example, the portion of each of the first bent segment 140₁ and the second bent segment 140₂ that is embedded in the liquified mold compound includes the second section 142 and a second portion 144₂ of the unexposed section 144. The first section 141 and a first portion 144₁ of the unexposed section 144 of each of the first bent segment 140₁ and the second bent segment 140₂ are not embedded in the liquified mold compound 20 in this example.

FIG. 9C illustrates the completed molded frame 130 having the portion of the first bent segment 140₁ and the portion of the second bent segment 140₂ embedded in molded frame 130. In this example, the first bent segment 140₁ and the second bent segment 140₂ are secured to (embedded in, in this example) the frame 130 such that the connection interface 150 attached to the second section 142 of each of the first bent segment 140₁ and the second bent segment 140₂ is at least partly exposed from a surface 130_{S} of the frame 130.

FIG. 9D illustrates an alternative arrangement of the molded frame 130. In this example, a portion of a bent segment 140 having no attached connection interface, for example the bent segment formed using the steps illustrated in FIGS. 3A through 3G, is embedded in the molded frame 130 such that the second section 142 of the bent segment 140 is at least partly exposed from a surface 130_{S} of the frame 130.

FIG. 9E illustrates securing a bent segment 140 to the frame 130. In this example, the bent segment 140 is secured to the frame 130 after the frame 130 is produced. The frame 130 includes preformed supports 132 to which the bent segment 140 is secured. The preformed supports 132 may include notches, loops, clips, rings, harnesses, recesses, and/or other structures formed on and/or in an inner wall 130_{W} of the frame 130. The preformed supports 132 may be part of the frame 130. In one example of the molded frame 130, the preformed supports 132 may be formed during a molding process used to form the molded frame 130. In this example, the bent segment 140 is secured to the frame 130 such that the connection interface 150 is partly exposed from the surface 130_{S} of the frame 130.

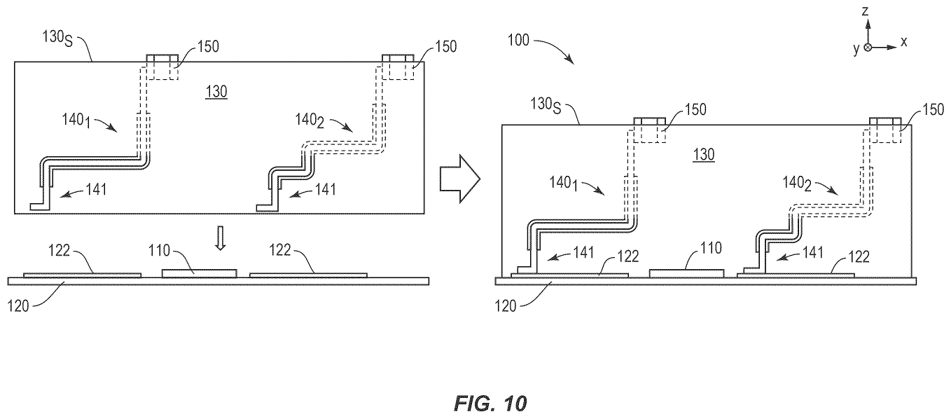

FIG. 10 illustrates attaching the frame 130 and ends of bent segments 140₁ and 140₂ secured to the frame 130 to the substrate 120 to produce the power module 100, according to an embodiment. Attaching the frame 130 to the substrate 120 of the power module 100 may include gluing or taping the frame 130 to the substrate 120, for example along an outer perimeter of the substrate 120.

The example of FIG. 10 illustrates attaching the first sections 141 of the first bent segment 140₁ and the second bent segment 140₂ to the substrate 120, specifically to the metallization layer 122 of the substrate 120. However, the attaching step illustrated in FIG. 10 may additionally or instead include attaching the second section 142 of the first bent segment 140₁ and/or the second bent segment 140₂ to the substrate 120, or attaching either section 141, 142 of either bent segment 140₁, 140₂ to an exposed contact of a power semiconductor die 110. Furthermore, the steps described with reference to FIG. 10 are not limited to attaching only first sections 141 at ends of the bent segments 140 to the substrate 120. For example, the steps described herein may be used to attach intermediate sections that are positioned between ends of a bent segment (e.g., in forming the power module 100 of FIG. 1C) and to attach multiple sections at ends of bent segments 140 to the substrate 120 (e.g., in forming the power module 100 of FIG. 1D).

Attaching the first section 141 or the second section 142 of each of the first bent segment 140₁ and the second bent segment 140₂ to the substrate 120 or contact pad of a power semiconductor die 110 may include soldering (e.g., preform or paste soldering), diffusion soldering, sintering, gluing, welding (e.g., ultrasonic welding, narrow gap welding, resistance welding, laser welding), or other methods of attachment. For example, the first section 141 or the second section 142 of the first bent segment 140₁ and/or the second bent segment 140₂ may be press fit or interface fit into a soldered or welded interface (e.g., a rivet).

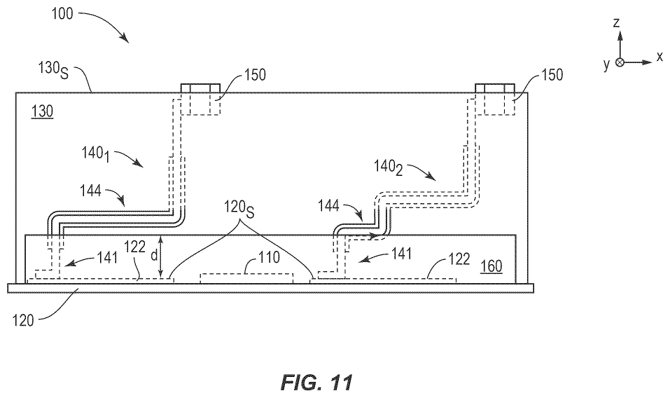

FIG. 11 illustrates adding the insulating gel 160 to the volume 105 of the power module 100, according to an embodiment. Specifically, FIG. 11 illustrates adding the insulating gel 160 to the volume 105 after attaching the frame 130 to the substrate 120 of the power module 100. The insulating gel 160 is added to the volume 105 such that the substrate 120 and the first section 141 of each of the first bent segment 140₁ and the second bent segment 140₂ are at least partly covered by the gel 160. Furthermore, an unexposed section 144 of each of the first bent segment 140₁ and the second bent segment 140₂ is at least partly uncovered by the insulating gel 160. The insulating gel 160 has a depth d measured from a surface 120_{S} of the substrate 120 to which the first section 141 of each of the first bent segment 140₁ and the second bent segment 140₂ is attached. In some examples, the depth d is less than or equal to 10 millimeters. For example, the depth d may be less than or equal to 5 millimeters.

Although the present disclosure is not so limited, the following numbered examples demonstrate one or more aspects of the disclosure.

Example 1. A method of forming power module connections, comprising: removing an electrically insulative coating from each of a first section and a second section of an elongated electrically conductive body; bending the elongated electrically conductive body in one or more dimensions to form a bent segment of the elongated electrically conductive body; severing the bent segment of the elongated electrically conductive body from a bulk of the elongated electrically conductive body such that each of the first section and the second section of the elongated electrically conductive body is at an end of the severed bent segment or is between ends of the severed bent segment; securing the bent segment to a frame of a power module; attaching the frame to a substrate of the power module; attaching at least one power semiconductor die to the substrate; and attaching the first section of the elongated electrically conductive body to the substrate or one of the power semiconductor dies.

Example 2. The method of example 1, wherein the bent segment is secured to the frame such that the second section of the elongated electrically conductive body is at least partly exposed from a surface of the frame.

Example 3. The method of example 1 or 2, further comprising: attaching a connection interface to the second section of the elongated electrically conductive body, wherein the bent segment is secured to the frame such that the connection interface is at least partly exposed from a surface of the frame.

Example 4. The method of example 3, wherein the connection interface is one of a nut, a rivet, a screw, or a pin.

Example 5. The method of example 3 or 4, wherein attaching the connection interface to the second section of the elongated electrically conductive body comprises soldering, diffusion soldering, sintering, gluing, welding, or crimping.

Example 6. The method of any of examples 1 through 5, further comprising: bending the second section of the elongated electrically conductive body in one or more dimensions.

Example 7. The method of any of examples 1 through 6, wherein attaching the first section of the elongated electrically conductive body to the substrate comprises soldering, diffusion soldering, sintering, gluing, or welding.

Example 8. The method of any of examples 1 through 7, further comprising: bending the first section of the elongated electrically conductive body in one or more dimensions.

Example 9. The method of any of examples 1 through 8, further comprising removing the electrically insulative coating from a third section of the elongated electrically conductive body, wherein after severing the bent segment of the elongated electrically conductive body from the bulk of the elongated electrically conductive body the third section of the elongated electrically conductive body is at an end of the bent segment or is between ends of the bent segment.

Example 10. The method of example 9, further comprising attaching the third section of the elongated electrically conductive body to the substrate.

Example 11. The method of example 9, wherein the bent segment is secured to the frame such that the third section of the elongated electrically conductive body is at least partly exposed from a surface of the frame.

Example 12. The method of example 9 or 11, further comprising: attaching a connection interface to the third section of the elongated electrically conductive body, wherein the bent segment is secured to the frame such that the connection interface is at least partly exposed from a surface of the frame.

Example 13. The method of any of examples 1 through 12, further comprising: after attaching the frame to the substrate of the power module, adding an insulating gel to a volume that is delimited by the substrate and the frame such that the substrate and the first section of the elongated electrically conductive body are at least partly covered by the gel and a portion of the bent segment between ends of the bent segment is at least partly uncovered by the gel.

Example 14. The method of example 13, wherein the insulating gel has a depth of less than or equal to 5 millimeters from a surface of the substrate to which the first section of the elongated electrically conductive body is attached.

Example 15. The method of any of examples 1 through 14, wherein the frame is an electrically insulative molded frame.

Example 16. The method of example 15, wherein securing the bent segment to the molded frame comprises: during formation of the molded frame, inserting a portion of the bent segment into a mold shaped to form the molded frame; and injecting a liquified mold compound into the mold such that the portion of the bent segment is embedded in the liquified mold compound.

Example 17. The method of any of examples 1 through 16, wherein securing the bent segment to the frame comprises securing the bent segment to one or more preformed notches, loops, clips, rings, harnesses, and/or recesses on an inner wall of the frame.

Example 18. The method of any of examples 1 through 17, wherein bending the elongated electrically conductive body in one or more dimensions to form the bent segment comprises twisting the elongated electrically conductive body about a longitudinal axis of the elongated electrically conductive body.

Example 19. The method of any of examples 1 through 18, wherein a cross-section of the elongated electrically conductive body is round, square, rectangular, or elliptical.

Example 20. The method of any of examples 1 through 19, wherein the elongated electrically conductive body has a flattened profile having a width in a first direction perpendicular to a longitudinal axis of the elongated electrically conductive body and a height in a second direction perpendicular to the first direction and the longitudinal axis of the elongated electrically conductive body, and wherein the width is greater than the height.

Example 21. The method of any of examples 1 through 20, wherein the bent segment is a first bent segment, and wherein the method further comprises: removing the electrically insulative coating from each of a third section and a fourth section of the elongated electrically conductive body; bending the elongated electrically conductive body in one or more dimensions to form a second bent segment of the elongated electrically conductive body; severing the second bent segment of the elongated electrically conductive body from the bulk of the elongated electrically conductive body such that each of the third section and the fourth section of the elongated electrically conductive body is at an end of the second bent segment or is between ends of the second bent segment; securing the second bent segment to the frame of the power module; and attaching the third section of the elongated electrically conductive body to the substrate.

Example 22. The method of example 21, wherein the first bent segment has a first bent profile and the second bent segment has a second bent profile that is different than the first bent profile.

Example 23. The method of example 21 or 22, wherein the frame is an electrically insulative molded frame, and wherein securing the first bent segment and the second bent segment to the molded frame comprises: during formation of the molded frame, inserting a portion of the first bent segment and a portion of the second bent segment into a mold shaped to form the molded frame; and injecting a liquified mold compound into the mold such that the portion of the first bent segment and the portion of the second bent segment are embedded in the liquified mold compound.

Example 24. The method of any of examples 1 through 23, wherein removing the electrically insulative coating from the first section and the second section of the elongated electrically conductive body, bending the elongated electrically conductive body in one or more dimensions to form a bent segment of the elongated electrically conductive body, and severing the bent segment of the elongated electrically conductive body from the bulk of the elongated electrically conductive body are completed using a single manufacturing tool.

Example 25. A power module, comprising: at least one power semiconductor die attached to a substrate; a frame attached to the substrate; and an elongated electrically conductive body segment secured to the frame and comprising: a first exposed section; a second exposed section; an unexposed section bent in one or more dimensions; and an electrically insulative material coating the unexposed section but not the first exposed section or the second exposed section, wherein the first exposed section of the elongated electrically conductive body segment is attached to the substrate.

Example 26. The power module of example 25, further comprising: an insulating gel at least partly filling a volume that is delimited by the substrate and the frame, such that the substrate and the first exposed section of the elongated electrically conductive body segment are at least partly covered by the gel and part of the unexposed section and the second exposed section are both at least partly uncovered by the gel, wherein the insulating gel is made of a different material than the electrically insulative material coating of the elongated electrically conductive body segment.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein can be combined with each other, unless specifically noted otherwise.

Although specific embodiments have been illustrated and described herein, it will be appreciated by those of ordinary skill in the art that a variety of alternate and/or equivalent implementations can be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of forming power module connections, comprising:
removing an electrically insulative coating from each of a first section and a second section of an elongated electrically conductive body;
bending the elongated electrically conductive body in one or more dimensions to form a bent segment of the elongated electrically conductive body;
severing the bent segment of the elongated electrically conductive body from a bulk of the elongated electrically conductive body such that each of the first section and the second section of the elongated electrically conductive body is at an end of the severed bent segment or is between ends of the severed bent segment;
securing the bent segment to a frame of a power module;
attaching the frame to a substrate of the power module;
attaching at least one power semiconductor die to the substrate; and
attaching the first section of the elongated electrically conductive body to the substrate or one of the power semiconductor dies.

2. The method of claim 1, wherein the bent segment is secured to the frame such that the second section of the elongated electrically conductive body is at least partly exposed from a surface of the frame.

3. The method of claim 1, further comprising:
attaching a connection interface to the second section of the elongated electrically conductive body,
wherein the bent segment is secured to the frame such that the connection interface is at least partly exposed from a surface of the frame.

4. The method of claim 3, wherein the connection interface is one of a nut, a rivet, a screw, or a pin.

5. The method of claim 3, wherein attaching the connection interface to the second section of the elongated electrically conductive body comprises soldering, diffusion soldering, sintering, gluing, welding, or crimping.

6. The method of claim 1, further comprising:
bending the second section of the elongated electrically conductive body in one or more dimensions.

7. The method of claim 1, wherein attaching the first section of the elongated electrically conductive body to the substrate comprises soldering, diffusion soldering, sintering, gluing, or welding.

8. The method of claim 1, further comprising:
bending the first section of the elongated electrically conductive body in one or more dimensions.

9. The method of claim 1, further comprising removing the electrically insulative coating from a third section of the elongated electrically conductive body, wherein after severing the bent segment of the elongated electrically conductive body from the bulk of the elongated electrically conductive body the third section of the elongated electrically conductive body is at an end of the bent segment or is between ends of the bent segment.

10. The method of claim 9, further comprising attaching the third section of the elongated electrically conductive body to the substrate.

11. The method of claim 9, wherein the bent segment is secured to the frame such that the third section of the elongated electrically conductive body is at least partly exposed from a surface of the frame.

12. The method of claim 9, further comprising:
attaching a connection interface to the third section of the elongated electrically conductive body,
wherein the bent segment is secured to the frame such that the connection interface is at least partly exposed from a surface of the frame.

13. The method of claim 1, further comprising:
after attaching the frame to the substrate of the power module, adding an insulating gel to a volume that is delimited by the substrate and the frame such that the substrate and the first section of the elongated electrically conductive body are at least partly covered by the gel and a portion of the bent segment between ends of the bent segment is at least partly uncovered by the gel.

14. The method of claim 13, wherein the insulating gel has a depth of less than or equal to 5 millimeters from a surface of the substrate to which the first section of the elongated electrically conductive body is attached.

15. The method of claim 1, wherein the frame is an electrically insulative molded frame.

16. The method of claim 15, wherein securing the bent segment to the molded frame comprises:
during formation of the molded frame, inserting a portion of the bent segment into a mold shaped to form the molded frame; and
injecting a liquified mold compound into the mold such that the portion of the bent segment is embedded in the liquified mold compound.

17. The method of claim 1, wherein securing the bent segment to the frame comprises securing the bent segment to one or more preformed notches, loops, clips, rings, harnesses, and/or recesses on an inner wall of the frame.

18. The method of claim 1, wherein bending the elongated electrically conductive body in one or more dimensions to form the bent segment comprises twisting the elongated electrically conductive body about a longitudinal axis of the elongated electrically conductive body.

19. The method of claim 1, wherein a cross-section of the elongated electrically conductive body is round, square, rectangular, or elliptical.

20. The method of claim 1, wherein the elongated electrically conductive body has a flattened profile having a width in a first direction perpendicular to a longitudinal axis of the elongated electrically conductive body and a height in a second direction perpendicular to the first direction and the longitudinal axis of the elongated electrically conductive body, and wherein the width is greater than the height.

21. The method of claim 1, wherein the bent segment is a first bent segment, and wherein the method further comprises:
removing the electrically insulative coating from each of a third section and a fourth section of the elongated electrically conductive body;
bending the elongated electrically conductive body in one or more dimensions to form a second bent segment of the elongated electrically conductive body;
severing the second bent segment of the elongated electrically conductive body from the bulk of the elongated electrically conductive body such that each of the third section and the fourth section of the elongated electrically conductive body is at an end of the second bent segment or is between ends of the second bent segment;
securing the second bent segment to the frame of the power module; and
attaching the third section of the elongated electrically conductive body to the substrate.

22. The method of claim 21, wherein the first bent segment has a first bent profile and the second bent segment has a second bent profile that is different than the first bent profile.

23. The method of claim 21, wherein the frame is an electrically insulative molded frame, and wherein securing the first bent segment and the second bent segment to the molded frame comprises:
during formation of the molded frame, inserting a portion of the first bent segment and a portion of the second bent segment into a mold shaped to form the molded frame; and
injecting a liquified mold compound into the mold such that the portion of the first bent segment and the portion of the second bent segment are embedded in the liquified mold compound.

24. The method of claim 1, wherein removing the electrically insulative coating from the first section and the second section of the elongated electrically conductive body, bending the elongated electrically conductive body in one or more dimensions to form a bent segment of the elongated electrically conductive body, and severing the bent segment of the elongated electrically conductive body from the bulk of the elongated electrically conductive body are completed using a single manufacturing tool.

25. A power module, comprising:
at least one power semiconductor die attached to a substrate;
a frame attached to the substrate; and
an elongated electrically conductive body segment secured to the frame and comprising:
a first exposed section;
a second exposed section;
an unexposed section bent in one or more dimensions; and
an electrically insulative material coating the unexposed section but not the first exposed section or the second exposed section,
wherein the first exposed section of the elongated electrically conductive body segment is attached to the substrate.

26. The power module of claim 25, further comprising:
an insulating gel at least partly filling a volume that is delimited by the substrate and the frame, such that the substrate and the first exposed section of the elongated electrically conductive body segment are at least partly covered by the gel and part of the unexposed section and the second exposed section are both at least partly uncovered by the gel,
wherein the insulating gel is made of a different material than the electrically insulative material coating of the elongated electrically conductive body segment.
